(19) United States
(12) Patent Application Publication
(10) Pub. No.: US 2013/0044411 A1
(43) Pub. Date: Feb. 21, 2013

(54) SUPPORTING APPARATUS FOR ELECTRONIC DEVICE

(71) Applicants: GUANG-XING ZHEN, Shenzhen City (CN); YI-SHENG LIN, New Taipei (TW); GUANG-YAO LEE, New Taipei (TW)

(72) Inventors: GUANG-XING ZHEN, Shenzhen City (CN); YI-SHENG LIN, New Taipei (TW); GUANG-YAO LEE, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen City (CN)

(21) Appl. No.: 13/241,277

(22) Filed: Sep. 23, 2011

(30) Foreign Application Priority Data
Aug. 15, 2011 (CN) 201110232870.8

(51) Int. Cl. H05K 7/00; F16M 11/04

(52) U.S. Cl. 361/679.01; 248/121

(57) ABSTRACT

A supporting apparatus for an electronic device includes a mounting mechanism, and a supporting assembly. The mounting mechanism includes a fixing bracket fixed to the electronic device, and a latching member mounted to the fixing bracket. The supporting assembly includes a mount, and a locking member fixed to the mount. The locking member includes a locking tab and a locking tongue opposite to the locking tab. The latch member is slidable between a locking position, where the latch member abuts the locking tongue to preventing the fixing bracket from moving away from the locking member, and an unlocking position, where the latch member disengages from the locking tongue to enable the fixing bracket to move away from the locking member.

### CROSS-REFERENCE OF RELATED APPLICATIONS

Relevant subject matter is disclosed in three pending U.S. patent applications, all titled “ELECTRONIC DEVICE WITH SUPPORTING APPARATUS”, with the application Ser. Nos. 13/198,730, 13/211,275, and 13/213,101, respectively filed on Aug. 5, 2011, Aug. 16, 2011, and Aug. 19, 2011, and another pending U.S. patent application, titled “ELECTRONIC DEVICE WITH MOUNTING APPARATUS”, with the application Ser. No. 13/209,458, filed on Aug. 15, 2011, which are all assigned to the same assignee as this patent application.

### BACKGROUND

1. Technical Field

The present disclosure relates to supporting apparatus, and particularly, to a supporting apparatus for an electronic device.

2. Description of Related Art

An electronic device, such as an all-in-one computer or a liquid crystal display, is secured to a supporting mechanism by a plurality of fasteners. However, it is time-consuming and often difficult to disassemble the supporting mechanism from the electronic device when the electronic device is to be hung on a wall.

### BRIEF DESCRIPTION OF THE DRAWINGS

The components of the drawings are not necessarily drawn to scale, the emphasis instead being placed upon clearly illustrating the principles of the embodiments. Moreover, in the drawings, like reference numerals designate corresponding parts throughout several views.

FIG. 1 is an isometric view of an exemplary embodiment of an assembled supporting apparatus and an electronic device, wherein the supporting apparatus includes a mounting mechanism, and a supporting assembly.

FIGS. 2 and 3 are exploded, isometric views of the mounting mechanism of FIG. 1, but viewed from different perspectives.

FIG. 4 is an exploded, isometric view of the supporting assembly of FIG. 1.

FIG. 5 is an isometric view of the assembled mounting mechanism and the electronic device of FIG. 1.

FIG. 6 is another isometric view of FIG. 4.

FIG. 7 is an isometric view of the assembled mounting mechanism and the supporting assembly of FIG. 1, but viewed from another perspective.

FIGS. 8 and 9 are enlarged views of the encircled portion VIII of FIG. 7, showing different states of the mounting mechanism.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

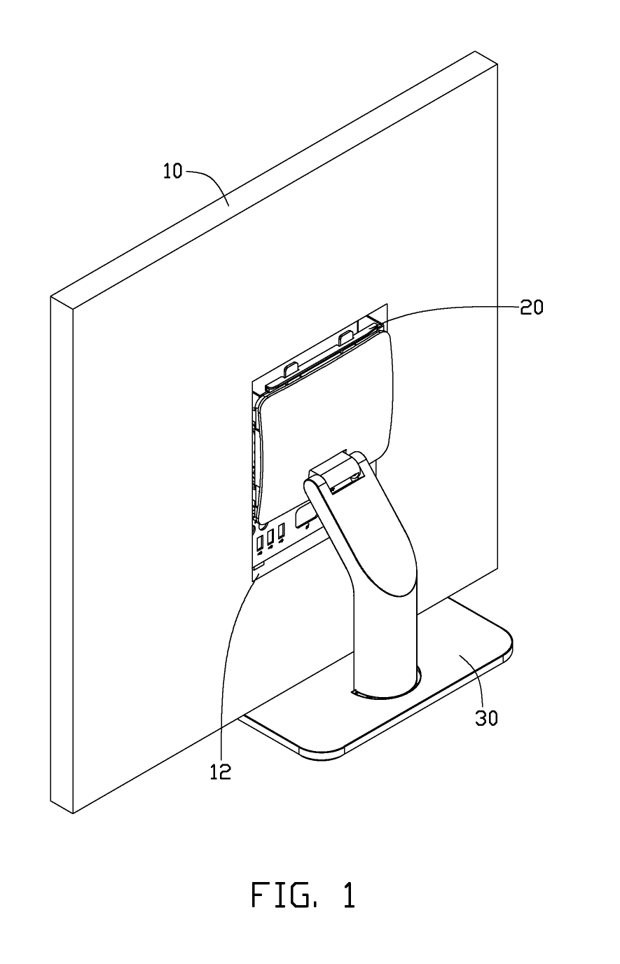

Referring to FIG. 1, an embodiment of a supporting apparatus for mounting to an electronic device 10 is provided. The supporting apparatus includes a mounting mechanism 20, and a supporting assembly 30. In one embodiment, the electronic device 10 is an all-in-one computer with a recess 12 defined in the rear side.

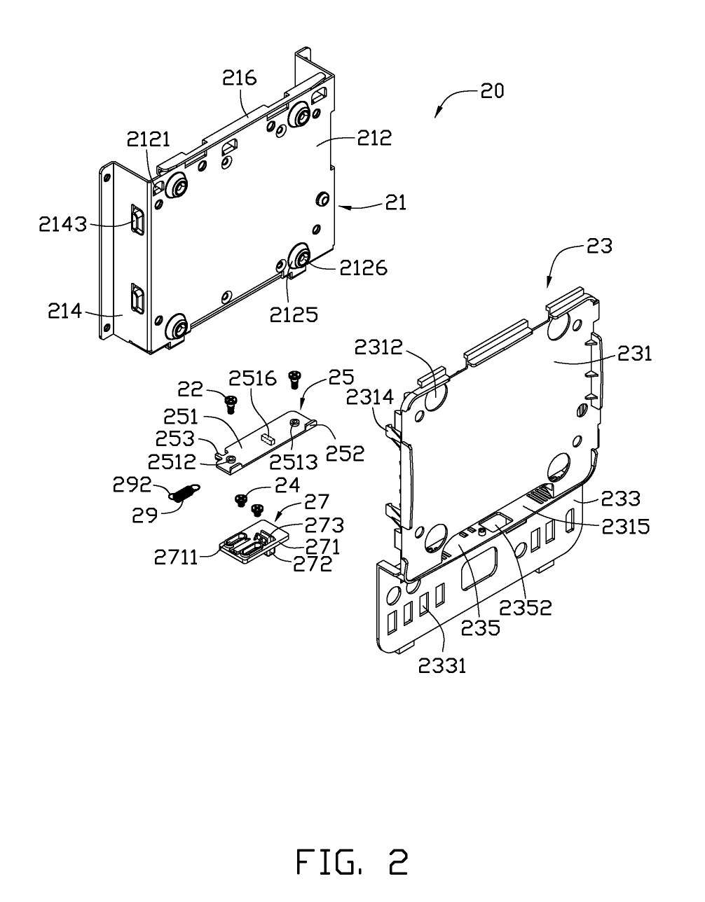

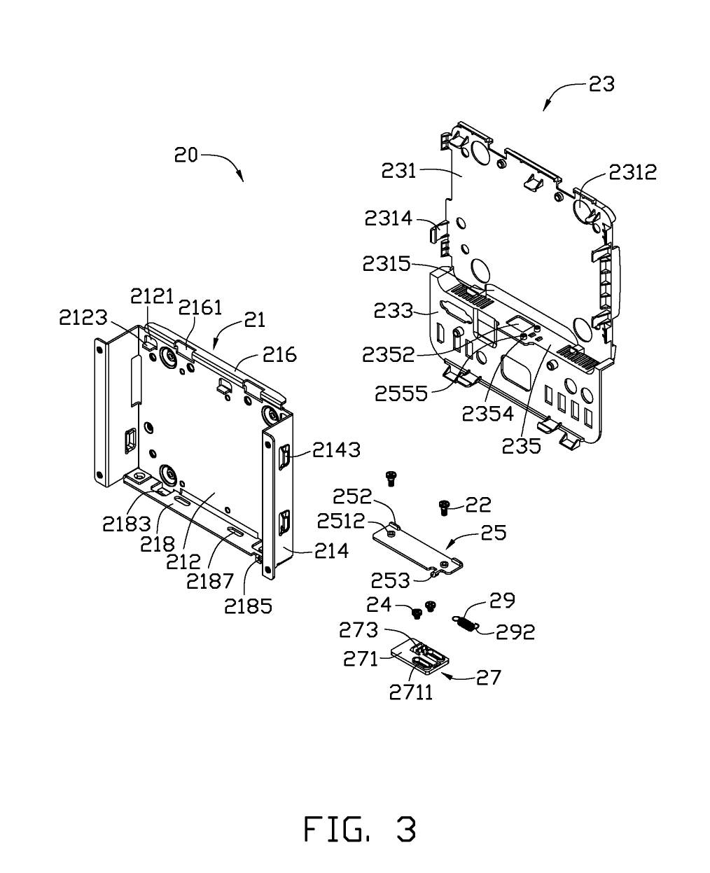

Referring to FIGS. 2 and 3, the mounting mechanism 20 includes a fixing bracket 21, a mounting bracket 23, a latch member 25, a manipulation member 27, a resilient member 29, two first sliding members 22, and two second sliding members 24.

The fixing bracket 21 includes a fixing plate 212, two wing plates 214 respectively extending from opposite sides of the fixing plate 212, a flange 216 extending rearwards form the top side of the fixing plate 212, and a locating plate 218 extending forwards from the bottom side of the fixing plate 212. The substantially L-shaped wing plates 213 extend from opposite ends of the fixing plate 212. Each wing plate 213 includes a first portion perpendicularly extending from the fixing plate 212, and a second portion perpendicularly extending from the distal end of the first portion opposite to the fixing plate 212. The second portions of the wing plates 213 extend away from each other. Two through holes 2121 are defined in the fixing plate 212. A positioning portion 2123 perpendicularly extends from each of the bottom walls which form the lower boundary of the through hole 2121. A plurality of bulges 2125 is formed on the rear side of the fixing plate 212, opposite the positioning portions 2123. Each of the bulges 2125 defines a fixing hole 2126. A plurality of positioning portions 2143 is formed on the first portion of each of the wing plates 2125. Two locking holes 2161 are defined at the joint of the fixing plate 212 and the flange 216. The locating plate 218 forms two positioning portions 2183 and an engagement tab 2185. The locating plate 218 defines two slide slots 2187.

The mounting bracket 23 includes a first shielding plate 231, a second shielding plate 233 parallel to and arranged below and ahead of the first shielding plate 231, and a connecting portion 235 connected between the bottom side of the first shielding plate 231 and the top side of the second shielding plate 233. The first shielding plate 231 defines a plurality of alignment holes 2312. A plurality of hooks 2314 extends forwards from the first shielding plate 231, arranged adjacent to the sides of the first shielding plate 231. An interference-avoiding slot 2315 is defined in the first shielding plate 231, adjacent to the connecting portion 235. The second shielding plate 233 defines a plurality of adapting holes 2331 for exposing the connectors of the electronic device 10. The connecting portion 235 defines an opening 2352. Two posts 2354, each axially defining a threaded hole 2555, are formed on the top of the connecting portion 235.

The latch member 25 includes a base plate 251, two blocking tabs 252 extending up from the rear side of the base plate 251, and an engagement tab 253 extending from one of the sides at the front of the base plate 251. Two posts 2512, each axially defining a threaded hole 2513, are formed on the top of the base plate 251. A securing block 2516 extends from the bottom of the base plate 251, opposite to the posts 2512.

The manipulation member 27 includes a base plate 271, a handle portion 272 protruding from the bottom of the base plate 271, and two opposite holding tabs 273 protruding from the top of the base plate 271. The base plate 271 defines two parallel slide slots 2711.

In one embodiment, the resilient member 29 is a coil spring, with a hook 292 formed at each end.

In one embodiment, the first and second sliding members 22 and 24 are screws with large diameter flat heads.

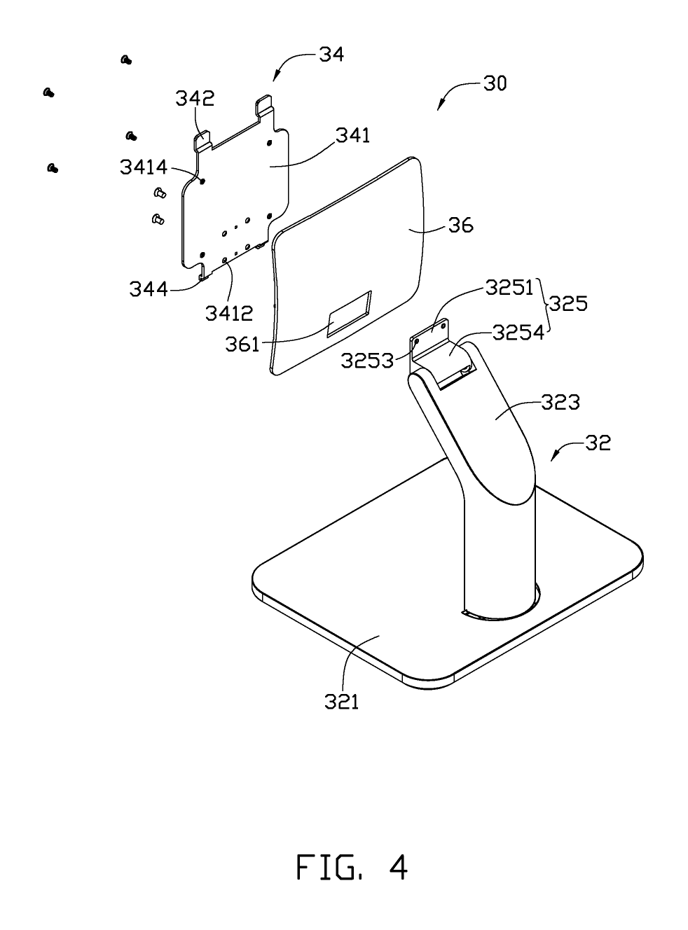

Referring to FIG. 4, the supporting assembly 30 includes a mount 32, a locking member 34, and a cover 36.

The mount 32 includes a bottom plate 321, a curved supporting arm 323 extending up from the bottom plate 321, and a coupling member 325 rotatably mounted to the top end of the supporting arm 323 opposite to the bottom plate 321. The coupling member 325 includes a connecting plate 3251, and a rotating portion 3254 slantingly protruding rearward from the rear side of the connecting plate 3251 and pivotably connected to the supporting arm 323. The connecting plate 3251 defines a plurality of fastening holes 3253.

The locking member 34 includes a base plate 341, two locking tabs 342 extending from the top side of the base plate 341, and two locking tongues 344 extending from the bottom side of the base plate 341. The locking tabs 342 and the locking tongues 344 are slightly offset forwards from the base plate 341. The base plate 341 defines a plurality of first fixing holes 3412 and a plurality of second fixing holes 3414.

The cover 36 defines a through hole 361. A plurality of mounting poles (not shown), each axially defining a threaded hole, extends from the front side of the cover 36 facing the locking member 34.

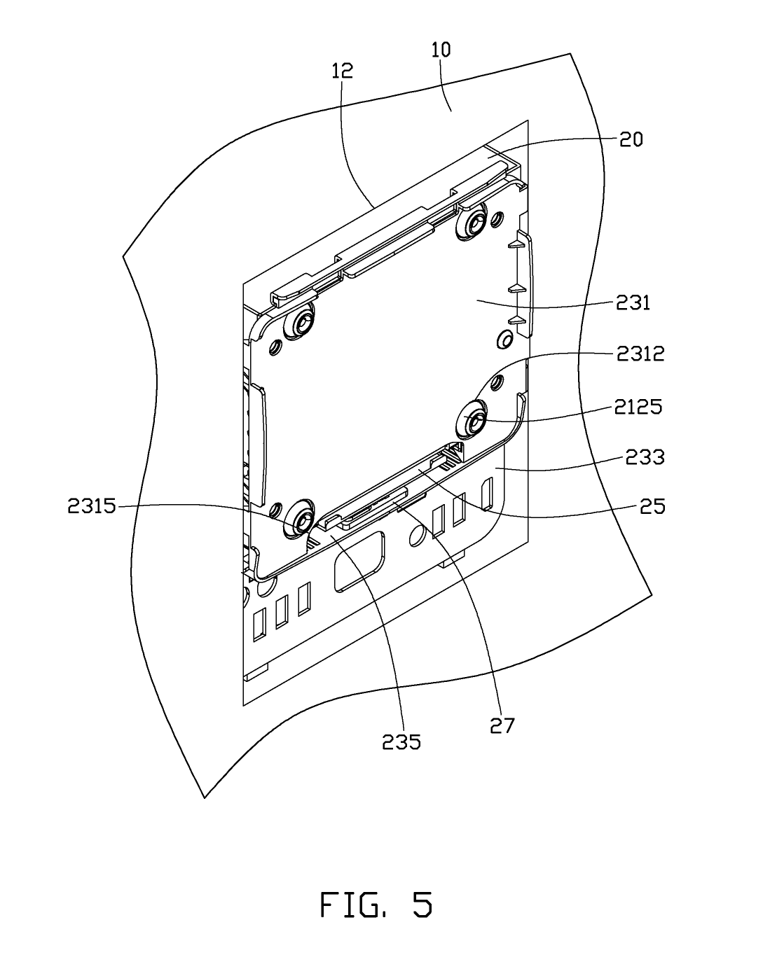

Referring to FIG. 5, to assemble the mounting mechanism 20 to the electronic device 10, the manipulation member 27 is disposed on the connecting portion 235 of the mounting bracket 23. The handle portion 272 is slidably received in the opening 2352 of the connecting portion 235. The posts 2354 of the connecting portion 235 are slidably received in the corresponding slide slots 2711 of the manipulation member 27. The second sliding members 24 extend through the slide slots 2711 and are fastened in the corresponding posts 2354, to slidably mount the manipulation member 27 to the mounting bracket 23. The securing block 2516 of the latch member 25 is securely sandwiched between the holding tabs 273 of the manipulation member 27, to fix the latch member 25 to the manipulation member 27. The fixing bracket 21 is attached to the mounting bracket 23. The hooks 2314 are engaged with the corresponding positioning portions 2123, 2143, and 2183. The bulges 2125 of the fixing bracket 21 are received in the corresponding alignment holes 2312 of the mounting bracket 23. The slide slots 2187 are aligned with the corresponding posts 2512 of the latch member 25. The first sliding members 22 slidably extend through the slide slots 2187 and are fastened in the corresponding posts 2512, to slidably connect the latch member 25 to the fixing bracket 21. The hooks 292 of the resilient member 29 are engaged with the engagement tab 2185 of the fixing bracket 21, and the engagement tab 253 of the latch member 25.

The mounting mechanism 20 is received in the recess 12 of the electronic device 10. A plurality of screws extends through the corresponding fixing holes 2126 of the fixing bracket 21 and fasten to the electronic device 10, to secure the mounting mechanism 20 to the rear side of the electronic device 10.

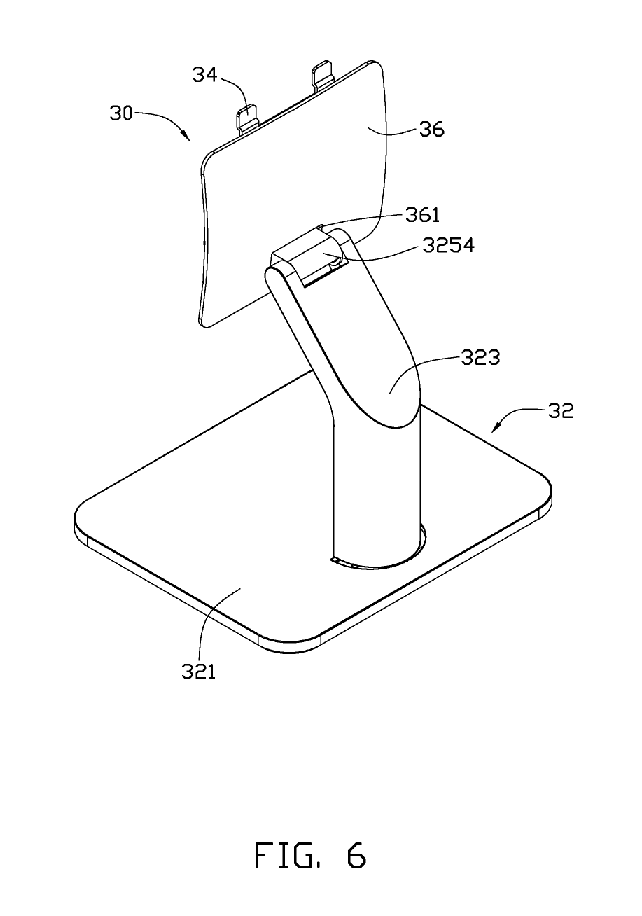

Referring to FIG. 6, to assemble the supporting assembly 30, the connecting plate 3251 of the mount 32 passes through the through hole 361 of the cover 36 to be located in front of the cover 36. The pivoting portion 3254 is received in the through hole 361. The locking member 34 abuts the connecting plate 3251 opposite to the supporting arm 323. The first fixing holes 3412 of the locking member 34 align with the fastening holes 3253 of the connecting plate 3251. The second fixing holes 3414 of the locking member 34 align with the mounting poles of the cover 36. A plurality of screws extends through the first and second fixing holes 3412 and 3414, and by virtue of the fastening holes 3253, secure the locking member 34 to the coupling member 325 and the cover 36. The connecting plate 3251 is sandwiched between the cover 36 and the locking member 34.

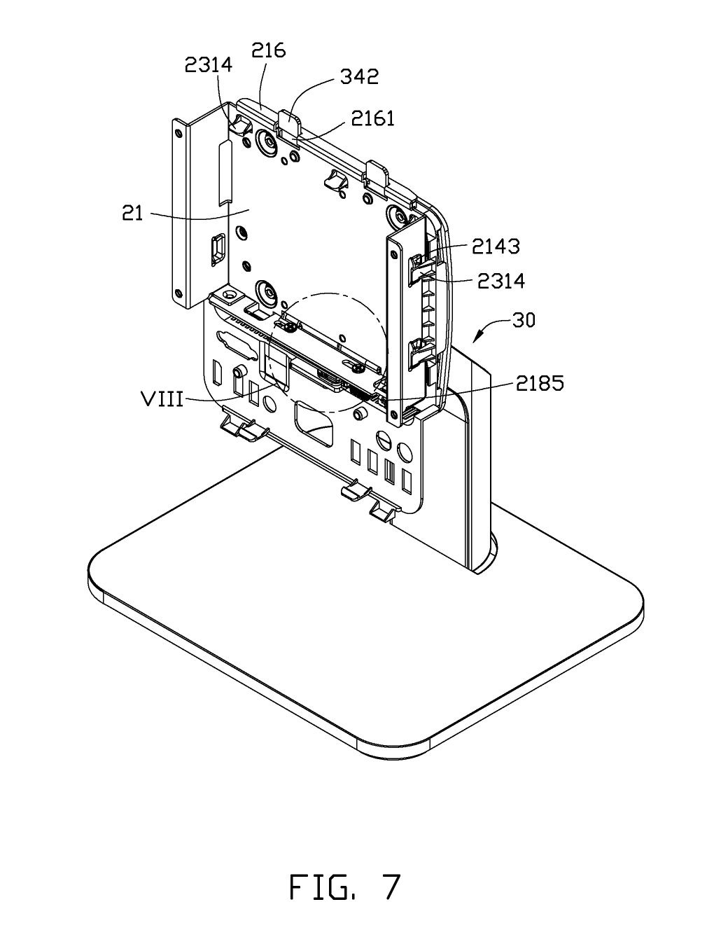

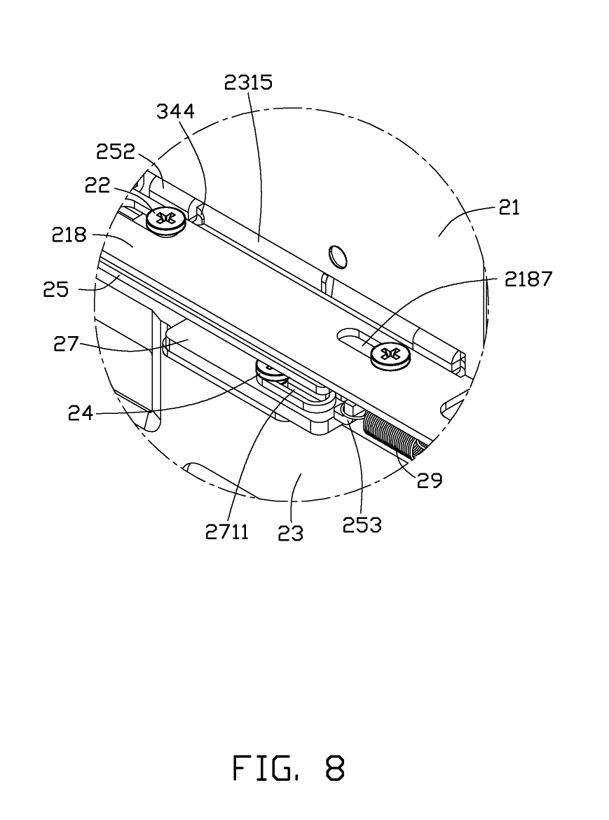

Referring to FIGS. 7 to 9, to mount the electronic device 10 to the supporting assembly 30, the locking tabs 342 of the locking member 34 are manipulated into the corresponding locking holes 2161 of the fixing bracket 21. The handle portion 272 of the manipulation member 27 is manipulated to slide the manipulation member 27 and the latch member 25 away from the engagement tab 2185 of the mounting bracket 21. The resilient member 29 is deformed. The base plate 341 of the locking member 34 abuts the first shielding plate 231 of the mounting bracket 23, with the locking tongues 344 extending through the interference-avoiding slot 2315. After the releasing member 27 is released, the resilient member 29 drives the latch member 25 to a locking position (shown in FIG. 8), where the blocking tabs 252 of the latch member 25 abut the front sides of the corresponding locking tongues 344 of the locking member 34, to prevent the latch member 25 moving forwards away from the locking member 34. In this way, the electronic device 10 is locked to the supporting assembly 30.

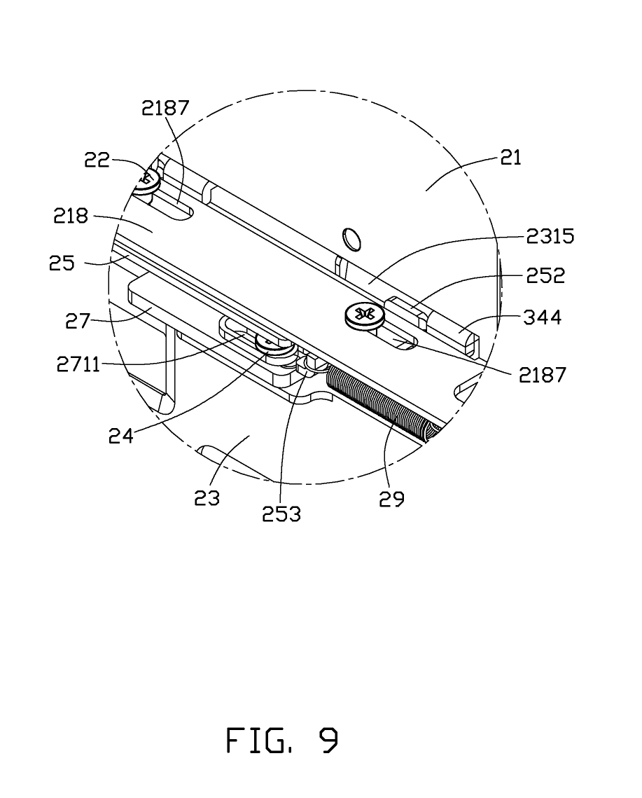

To detach the electronic device 10 from the supporting assembly 30, the handle portion 272 of the manipulation member 27 is manipulated to slide the manipulation member 27 and the latch member 25 away from the engagement tab 2185 of the mounting bracket 21, to an unlocking position (shown in FIG. 9), where the blocking tabs 252 of the latch member 25 are disengaged from the corresponding locking tongues 344 of the locking member 34. The electronic device 10 can be tilted relative to the locking member 34, thereby moving the latch member 25 forwards away from the locking member 34 The electronic device 10 is driven down to disengage the locking tabs 342 of the locking member 34 from the corresponding locking holes 2161 of the fixing bracket 21. In this way, the electronic device 10 may be detached from the supporting assembly 30.

Even though numerous characteristics and advantages of the embodiment(s) have been set forth in the foregoing description, together with details of the structures and functions of the embodiment(s), the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A supporting apparatus for an electronic device, the supporting apparatus comprising:
a mounting mechanism comprising a fixing bracket fixed to the electronic device, and a latch member slidably mounted to a first side of the fixing bracket, the fixing bracket defining a locking hole in a second side of the fixing bracket opposite to the first side; and
a supporting assembly comprising a mount, and a locking member fixed to the mount, the locking member comprising a locking tab and a locking tongue respectively arranged at opposite sides of the locking member, the locking tab detachably engaged in the locking hole of the fixing bracket;
wherein the latch member is slidable between a locking position, where the latch member abuts the locking tongue to prevent the fixing bracket from moving away from the locking member, and an unlocking position, where the latch member disengages from the locking tongue to enable the fixing bracket to move away from the locking member.

2. The supporting apparatus of claim 1, wherein the mounting mechanism further comprises a resilient member connected between the fixing bracket and the latch member, to bias the latch member towards the locking position.

3. The supporting apparatus of claim 2, wherein each of the fixing bracket and the latch member comprises an engagement tab, the resilient member is a coil spring with two hooks formed at opposite ends, to respectively engage with the engagement tabs of the fixing bracket and the latch member.

4. The supporting apparatus of claim 1, wherein the mounting mechanism further comprises a sliding member, the fixing bracket comprises a locating plate on the first side of the fixing bracket, the fixing bracket defines a slide slot, the latch member comprises a post, the sliding member is slidably received in the slide slot of the fixing bracket, and fastened to the post of the latch member.

5. The supporting apparatus of claim 4, wherein the post of the latch member axially defines a threaded hole, the sliding member is a screw engaged in the threaded hole.

6. The supporting apparatus of claim 1, wherein the mount of the supporting assembly comprises a bottom plate, a supporting arm extending up from the bottom plate, and a coupling member rotatably mounted to a top end of the supporting arm opposite to the bottom plate, the coupling member is fixed to the locking member.

7. The supporting apparatus of claim 6, wherein the coupling member comprises a connecting plate fixed to the fixing bracket, and a rotating portion protruding from a side of the connecting plate and pivotably connected to the supporting arm.

8. The supporting apparatus of claim 7, wherein the supporting assembly further comprises a cover fixed to the locking member, to sandwich the connecting plate with the locking member, and the cover defines a through hole through which the rotating portion of the coupling member extends.

9. An assembly comprising:
an electronic device;
a mounting mechanism comprising a fixing bracket fixed to the electronic device, and a latch member slidably mounted to a first side of the fixing bracket, the fixing bracket defining a locking hole in a second side of the fixing bracket opposite to the first side; and
a supporting assembly comprising a mount, and a locking member fixed to the mount, the locking member comprising a locking tab and a locking tongue respectively arranged at opposite sides of the locking member, the locking tab detachably engaged in the locking hole of the fixing bracket;
wherein the latch member is slidable between a locking position, where the latch member abuts the locking tongue to prevent the fixing bracket from moving away from the locking member, and an unlocking position, where the latch member disengages from the locking tongue to enable the fixing bracket to move away from the locking member.

10. The assembly of claim 9, wherein the mounting mechanism further comprises a first sliding member, the fixing bracket comprises a locating plate on the first side of the fixing bracket, the fixing bracket defines a slide slot, the latch member comprises a post, the first sliding member is slidably received in the slide slot of the fixing bracket, and fastened to the post of the latch member.

11. The assembly of claim 10, wherein the mounting mechanism further comprises a mounting bracket fixed to a surface of the fixing bracket opposite to the electronic device, and an manipulation member fixed to the latch member, the mounting bracket defines an opening, the manipulation member comprises a handle portion opposite to the latch member, and is slidably received in the opening of the mounting bracket.

12. The assembly of claim 11, wherein the mounting mechanism further comprises a second sliding member, the mounting bracket comprises a post, the manipulation member defines a slide slot aligning with the post of the mounting bracket, the second sliding member is slidably received in the slide slot of the manipulation member and fastened to the post of the mounting bracket.

13. The assembly of claim 12, wherein each of the posts of the latch member and the mounting bracket axially defines a threaded hole, the first and the second sliding members are screws engaged in the threaded holes of the corresponding posts of the latch member and the mounting bracket.

14. The assembly of claim 13, wherein the electronic device is an all-in-one computer.
